(19) United States
(12) Patent Application Publication
(10) Pub. No.: US 2006/0225656 A1
(43) Pub. Date: Oct. 12, 2006

(54) Plasma processing apparatus, slot antenna and plasma processing method

(75) Inventor: Takahiro Horiguchi, Kanagawa (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTON LIMITED, Minato-ku (JP)

(21) Appl. No.: 11/393,918

(22) Filed: Mar. 31, 2006

(30) Foreign Application Priority Data
Apr. 11, 2005 (JP) 2005-113833

(51) Int. Cl. B01J 19/08; C23C 16/00; G21H 1/00

(52) U.S. Cl. 118/723 MW; 118/724; 427/457

(57) ABSTRACT

A microwave plasma processing apparatus 100 includes a processing chamber 10, a waveguide 22, a slot antenna 23, a dielectric member 24, a first cooling unit 60 and a second cooling unit 80. As a liquid coolant flows through a flow passage 61 disposed at the slot antenna 23, the dielectric member 24 is cooled by the first cooling unit 60. The second cooling unit 80 supplies a gas to circulate through a gas intake port and a gas outlet port formed at the waveguide 22, thereby cooling the dielectric member 24. While the dielectric member 24 is thus cooled, a processing gas is raised to plasma with microwaves having been transmitted through the dielectric member 24 via the waveguide 22 and the slot antenna 23, and a substrate W is processed with the plasma thus generated.

### CROSS REFERENCE TO RELATED APPLICATION

The disclosure of Japanese Patent Application No. JP 2005-113833 filed on Apr. 11, 2005 is incorporated herein by reference in its entirety.

### BACKGROUND OF THE INVENTION

1. Field of the Invention

The present invention relates to a method for cooling a plasma processing apparatus.

2. Description of the Related Art

Today, high-speed plasma processing is often executed on large-size substrates by using high-power microwaves in plasma processing apparatuses. Processes such as CVD (chemical vapor deposition) processing are usually executed in plasma processing apparatuses by using high-power microwaves over extended lengths of time.

Such a high-power microwave device in a plasma processing apparatus generates very intense plasma inside the processing chamber. As a result, a dielectric member disposed at a position near the area where the intense plasma is generated becomes rapidly heated to a very high temperature. In addition, if microwaves are radiated into an apparatus over an extended period of time (e.g., one hour), the dielectric member is heated over a long period of time by the plasma generated in the apparatus and by the microwaves.

If such conditions manifest during plasma processing, the dielectric member, which does not transfer heat readily and is thus heat-retentive, becomes hot throughout its entirety, and its temperature at certain locations becomes especially high. If the plasma is inconsistent, a significant difference in the temperature will occur within the dielectric member, leading to a manifestation of thermal stress, and the dielectric member may become cracked due to the thermal stress.

As a means for addressing this problem, a technology for air-cooling the dielectric member with a cooling gas such as air has been proposed in the related art.

However, the technology disclosed in the related art requires a large quantity of cooling gas to be used to cool the dielectric member, which is bound to raise the production cost. In addition, the dielectric member, the size of which is likely to be large since the plasma process of large-size substrates has become common in recent years, cannot be fully cooled through air-cooling alone, and it appears the cracking of the dielectric member occurring during a process cannot be prevented by adopting the air-cooling technology alone.

a plasma processing apparatus, a slot antenna and a plasma processing method, to be adopted to cool a dielectric member by using a liquid coolant is to provide to address the problems discussed above.

### SUMMARY OF THE INVENTION

At least one of the problems discussed above is addressed in an aspect of the present invention by providing a plasma processing apparatus for executing plasma processing on a substrate by using the plasma. The plasma processing apparatus includes a waveguide unit configured to propagate microwaves, a dielectric member configured to transmit the microwaves propagated via the waveguide unit, a first cooling unit configured to cool the dielectric member by using a liquid coolant, and a processing chamber configured to execute plasma processing on a substrate by raising a processing gas raised to plasma with the microwaves transmitted through the dielectric member.

A slot antenna including, a slot configured to transmit microwaves toward a dielectric member; and a flow passage configured to flow a liquid coolant to cool the dielectric member.

A plasma processing method including, a step for propagating microwaves through a waveguide unit, a step for transmitting the microwaves through a dielectric member via the waveguide unit while supplying a liquid coolant through a flow passage formed at a slot antenna so as to cool the dielectric member; and a step for executing plasma processing on a substrate in a processing chamber by raising a processing gas to plasma with the microwaves transmitted through the dielectric member.

### BRIEF DESCRIPTION OF THE DRAWINGS

FIG. 1 is a sectional view of the microwave plasma processing apparatus achieved in an embodiment of the present invention;

FIG. 2 is a partial enlargement of the microwave plasma processing apparatus in FIG. 1;

FIG. 3 shows the relationship between the localized heating at the dielectric member and cracking of the dielectric member in an embodiment of the present invention;

FIG. 4 shows the positions at which temperature sensors are disposed at the dielectric member in an embodiment of the present invention;

FIG. 5 shows the first cooling unit (flow passage) in an embodiment of the present invention;

FIG. 6 is a sectional view taken across the 1-1′ plane in FIG. 5;

FIG. 7 illustrates the effect achieved with the first cooling unit in an embodiment of the present invention;

FIG. 8 shows the second cooling unit in an embodiment of the present invention;

FIG. 9 presents test results obtained by cooling the dielectric member during plasma processing in an embodiment of the present invention;

FIG. 10 shows a flow passage adopting another form in an embodiment of the present invention;

FIG. 11 shows a flow passage adopting another form in an embodiment of the present invention; and

FIG. 12 presents another example of the second cooling unit in an embodiment of the present invention.

### DETAILED DESCRIPTION OF THE EMBODIMENTS

The following is a detailed explanation of the embodiments of the present invention given in reference to the attached drawings. It is to be noted that in the specification and the drawings, the same reference numerals are assigned to components having substantially identical functions and structural features to preclude the necessity for a repeated explanation thereof.

(Structure of Microwave Plasma Processing Apparatus)

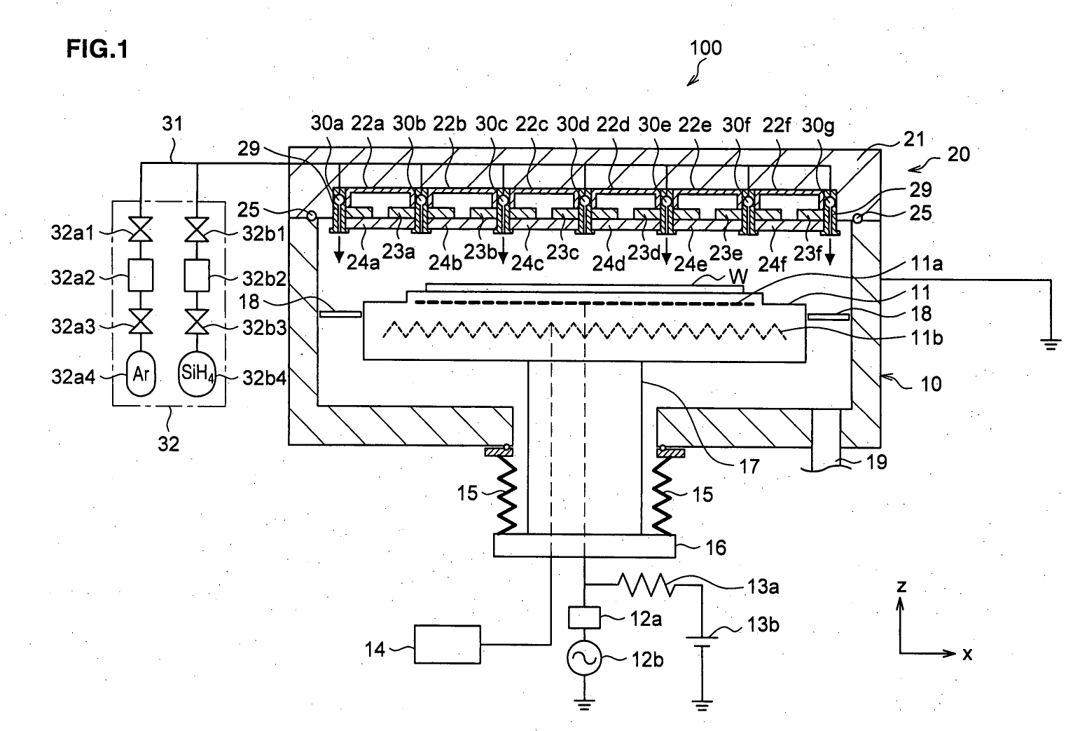

First, the structure of the microwave plasma processing apparatus achieved in an embodiment of the present invention is explained in reference to FIG. 1. FIG. 1 is a sectional view of a microwave plasma processing apparatus 100, taken along a plane ranging parallel to an x axis and a z axis. The microwave plasma processing apparatus 100 represents an example of a plasma processing apparatus.

The microwave plasma processing apparatus 100 includes a casing constituted with a processing chamber 10 and a lid unit 20. The processing chamber 10, assuming a rectangular parallelopiped shape with an open top and a solid bottom, is grounded. The processing chamber 10 is constituted of a metal such as aluminum (Al). Inside the processing chamber 10, a susceptor 11 to function as a stage on which a glass substrate W (hereafter referred to as a “substrate”), for instance, is placed, is disposed at a substantial center thereof. The susceptor 11 may be constituted of, for instance, aluminum nitride.

Inside the susceptor 11, a power supply unit 11a and a heater 11b are disposed. The power supply unit 11a is connected to a high-frequency power source 12b via a matcher 12a (e.g., a capacitor). The power supply unit 11a is also connected with a high-voltage DC power source 13b via a coil 13a. The matcher 12a, the high-frequency power source 12b, the coil 13a and the high-voltage DC power source 13b are disposed outside the processing chamber 10, and the high-frequency power source 12b and the high-voltage DC power source 13b are grounded.

The power supply unit 11a applies a specific level of bias voltage inside the processing chamber 10 by using high-frequency power output from the high-frequency power source 12b. A DC voltage output from the high-voltage DC power source 13b is used to electrostatically hold the substrate W via the power supply unit 11a.

An AC power source 14 disposed outside the processing chamber 10 is connected to the heater 11b so as to sustain the temperature at the substrate W at a predetermined level with an AC voltage output from the AC power source 14.

A round opening is formed at the bottom surface of the processing chamber 10, and one end of a bellows 15 is attached near the external circumference of the opening toward the outside of the processing chamber 10. An elevating plate 16 is fixed to the other end of the bellows 15. Thus, the opening at the bottom surface of the processing chamber 10 is sealed off by the bellows 15 and the elevating plate 16.

The susceptor 11, supported by a cylindrical member 17 disposed above the elevating plate 16, moves up/down as one with the elevating plate 16 and the cylindrical member 17. The height of the susceptor 11 is thus adjusted in correspondence to the type of process being executed.

Around the susceptor 11, a baffle plate 18 for controlling the gas flow inside the processing chamber 10 in a desirable condition is disposed. In addition, a gas discharge pipe 19 connected to a vacuum pump (not shown) is mounted at the bottom surface of the processing chamber 10. The gas in the processing chamber 10 is discharged via the vacuum pump until a desired degree of vacuum is achieved.

The lid unit 20 is disposed atop of the processing chamber 10 so as to seal the processing chamber 10. As is the processing chamber 10, the lid unit 20 is constituted of a metal such as aluminum (Al). Also, the lid unit 20 is grounded as is the processing chamber 10.

The lid unit 20 includes a lid main body 21, waveguides 22a through 22f, slot antennas 23a through 23f and dialectic members 24a through 24f.

A space of the processing chamber 10 and the lid unit 20 is sealed so as to sustain a high level of airtightness via an O-ring 25 disposed between the external circumference of the lower surface of the lid main body 21 and the external circumference of the upper surface of the processing chamber 10, with the waveguides 22a through 22f formed under the lid main body 21.

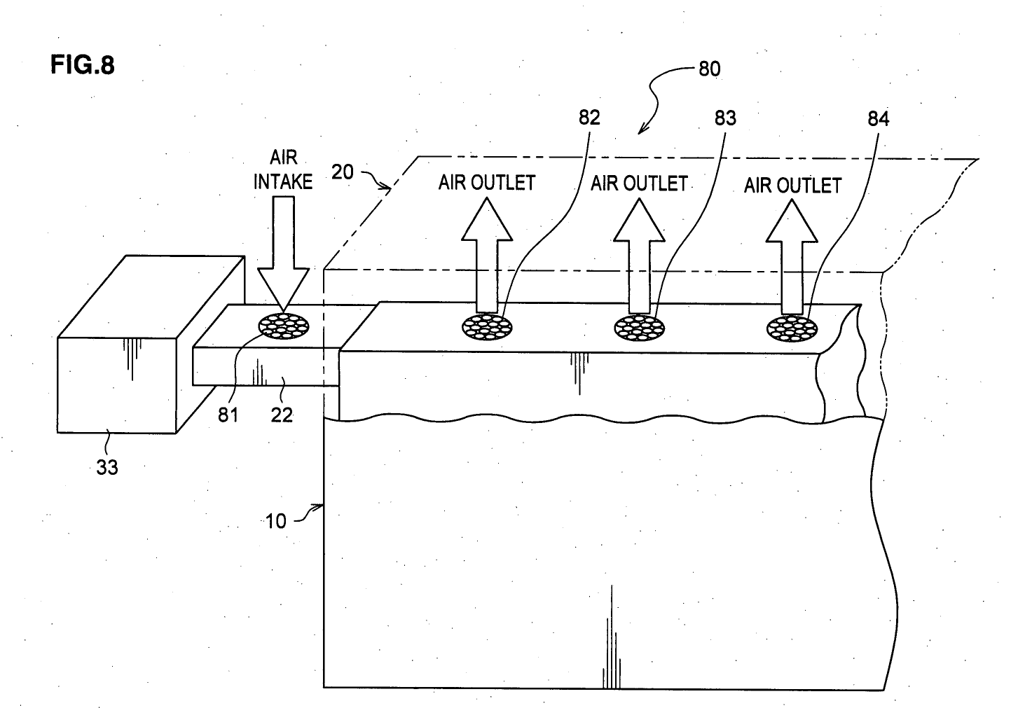

The waveguides 22 are rectangular waveguides each having a rectangular section perpendicular to the axis thereof, and are connected to a microwave generator 33 (see FIG. 8). For instance, in a TE10 mode (TE: transverse electric wave; a wave with a magnetic field containing a microwave advancing direction component), the wider pipe walls at each waveguide 22 constitute H surfaces parallel to the magnetic field and the narrow pipe walls constitute E surfaces parallel to the electrical field. The orientation of the longer side (the width of the waveguide) and the shorter side of the section of the waveguide 22 taken along the direction perpendicular to the axis thereof (along the length thereof) is adjusted in correspondence to the mode (the electromagnetic field distribution inside the waveguide).

The slot antennas 23a through 23f are respectively disposed under the waveguides 22a through 22f. The slot antennas 23a through 23f are constituted of a metal such as aluminum (Al). The slot antennas 23a through 23f each include a plurality of slots (openings) formed therein. It is to be noted that the waveguides 22 and the slot antennas 23 constitute a waveguide unit through which the microwaves are propagated.

Under the slot antennas 23a through 23f, the dialectic members 24a through 24f are respectively disposed. The dialectic members 24 are constituted of, for instance, quartz or alumina (aluminum oxide: Al₂O₃) so as to allow the microwaves to be transmitted.

The dialectic members 24a through 24f are each supported near the circumference thereof by metal beams 29. Inside the beams 29, gas intake pipes 30a through 30g are disposed. A processing gas supply source 32 is connected to the gas intake pipes 30a through 30g via a gas passage 31.

The processing gas supply source 32 includes a valve 32a1, a mass flow controller 32a2, a valve 32a3, an argon gas supply source 32 a4, a valve 32b1, a mass flow controller 32b2, a valve 32b3 and a silane gas supply source 32b4.

By controlling the valve 32a1, the valve 32a3, the valve 32b1 and the valve 32b3 so as to open/close them as required, the argon gas or the silane gas can be selectively supplied into the processing chamber 10 from the processing gas supply source 32. In addition, the flow rates of the respective processing gases are controlled via the mass flow controller 32a2 and the mass flow controller 32b2, so as to achieve desired levels of gas concentration.

In the microwave plasma processing apparatus 100 structured as described above, microwaves at a frequency of, for instance, 2.45 GHz, output from the microwave generator 33 are propagated via the waveguides 22 to the slot antennas 23, and the microwaves are then propagated to the dialectic members 24 through the slots formed at the slot antennas 23. With the microwaves having been transmitted through the dialectic members 24 and radiated into the processing chamber, the processing gas supplied into the processing chamber 10 is raised to plasma and the substrate W placed in the processing chamber 10 is processed with the plasma thus generated in the microwave plasma processing apparatus 100.

(Plasma Generation Conditions)

Next, three major factors that cause uneven plasma while the substrate W in the processing chamber 10 undergoes plasma processing in the microwave plasma processing apparatus 100 are explained.

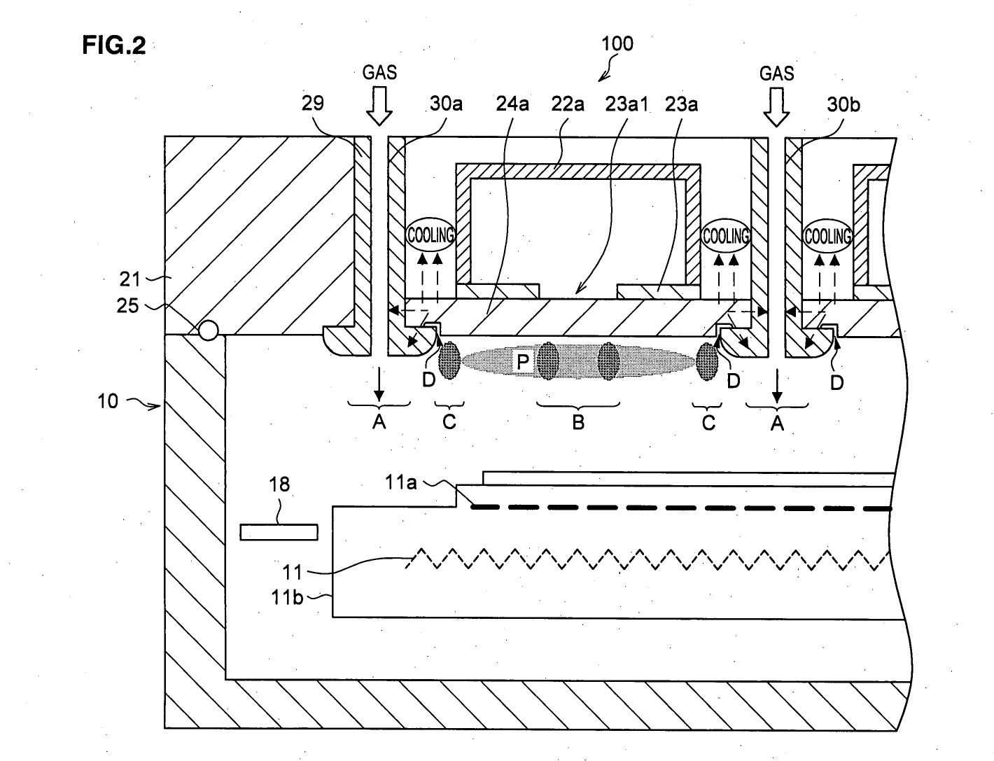

As described above, the microwaves are propagated through the waveguides 22, travel through the slots at the slot antennas 23, transmitted through the dialectic member 24 and finally propagated into the processing chamber 10. The processing gas is supplied through the gas intake pipes 30. FIG. 2 shows plasma (P) generated in the space under the dialectic member 24a by raising the processing gas with the power of the microwaves having traveled through the slot 23a, transmitted through the dielectric member 24a and radiated into the processing chamber 10.

Assuming that the process is executed under fixed processing conditions, i.e., assuming that the conditions such as the pressure inside the processing chamber 10 during the process and the power level of the microwaves propagated into the processing chamber are fixed, the surface wave propagated at the dielectric member 24 may not always be allowed to spread out inside the processing chamber 10 depending upon the type of gas supplied along the direction A through the gas intake pipes 30. If the surface wave is not allowed to spread out, the plasma becomes uneven.

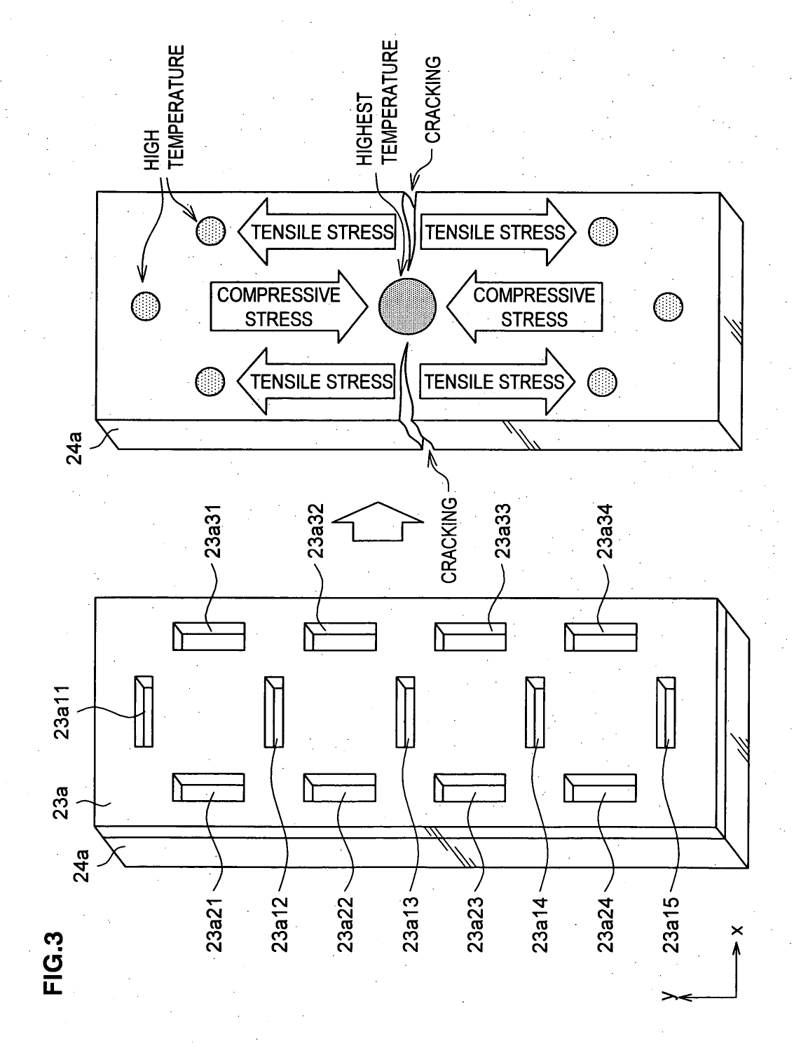

The second cause of uneven distribution of plasma is explained next. As shown on the left-hand side in FIG. 3, a plurality of slots are formed at the slot antenna 23a disposed at one surface of the dielectric member 24a in close contact with the dielectric member 24a. Among these slots, central slots 23a11 through 23a15 are formed over intervals equal to ½ of the guide wavelength. Left side slots 23a21 through 23a24 and right side slots 23a31 through 23a34 are each formed substantially halfway between a pair of successive slots among the slots 23a11 through 23a15 along the y axis (at positions each corresponding to ¼ of the guide wavelength).

At the slot antenna with slots formed as described above, the peaks and troughs in the standing wave of the microwaves propagated through the waveguide 22a in FIG. 2 are positioned above the central slots 23a11 through 23a15, whereas the nodes (where the peaks and troughs meet) of the standing wave are positioned above the left side slots 23a21 through 23a24 and the right side slots 23a31 through 23a34. As a result, intense microwaves from the individual slots are transmitted through the dielectric member 24a and are then propagated in the area B in FIG. 2. For this reason, the intensity of the plasma generated in the area B is higher than that of plasma generated in other areas, leading to unevenness in the plasma P.

Lastly, the third cause of unevenness in plasma is explained. The dielectric member 24a is supported near the circumference thereof by the beams 29. Gaps D are present between the beams 29 and the circumference of the dielectric member 24a as shown in FIG. 2. The microwaves having been transmitted through the dialectic member 24a are propagated as a surface wave along the lower surface of the dielectric member 24a. The propagated microwaves enter the gaps D, and while the microwaves remained in the gaps D, they are continuously reflected inside the gaps D. The microwaves reflected in the gaps D cause unstable generation of plasma or abnormal discharge in areas C. Such a phenomenon destabilizes the plasma P generated under the dielectric member 24a, resulting in unevenness in the plasma P.

(Cracking of the Dialectic Members)

As unevenness in the plasma P occurs as described above, the dielectric member 24a becomes heated particularly intensely over areas where the plasma intensity is high (e.g., areas under the slots in FIG. 3). The temperature in the area around the dielectric member 24a, whereas the heat can be released in the peripheral area of the dielectric member 24a via the beams 29 acting as conductors, remains low. Thus, the temperature at portions of the dielectric member 24a near the areas where the plasma intensity is high becomes higher than the temperature in the peripheral area, creating a temperature difference within the dielectric member 24a.

Such a temperature difference occurring inside the dielectric member 24a causes cracking of the dielectric member 24a for the following reason.

For instance, if the temperature of the dielectric member 24a is at its highest at the center of the dielectric member 24a, the dielectric member 24a thermally expands to the greatest extent at the center, as shown on the right side of FIG. 3. Against the force of thermal expansion, the dielectric member 24a strains to retain its initial shape. As a result, a compressive stress manifests at the center of the dialectic member 24a along the y axis toward the center of the dielectric member 24a.

At the same time, at the both ends of the dielectric member 24a along the x axis, tensile stress manifests along the y axis toward the outside of the dielectric member 24a against the compressive stress having manifested at the center. However, the temperature at the both ends of the dielectric member 24a along the x axis is lower than the temperature in the central area of the dielectric member 24a. This means that the dielectric member 24a does not thermally expand as much at the both ends as it does at the center thereof. As a result, the dielectric member 24a becomes distorted, which ultimately results in cracking of the dielectric member 24a at the both ends thereof.

It is to be noted that an explanation is given above on a temperature difference manifesting along a plane (the xy plane) of the dielectric member 24. However, a temperature difference also occurs inside the dielectric member 24 along the thickness (along the z axis) of the dielectric member 24. Thus, distortion of the dielectric member 24 is actually caused by the temperature difference manifesting along the plane of the dielectric member 24 and the temperature difference manifesting along the thickness of the dielectric member, and the dielectric member 24 becomes cracked over an area where the extent of the distortion is at its greatest.

(Test Results Obtained by Heating Dielectric Member with Burner)

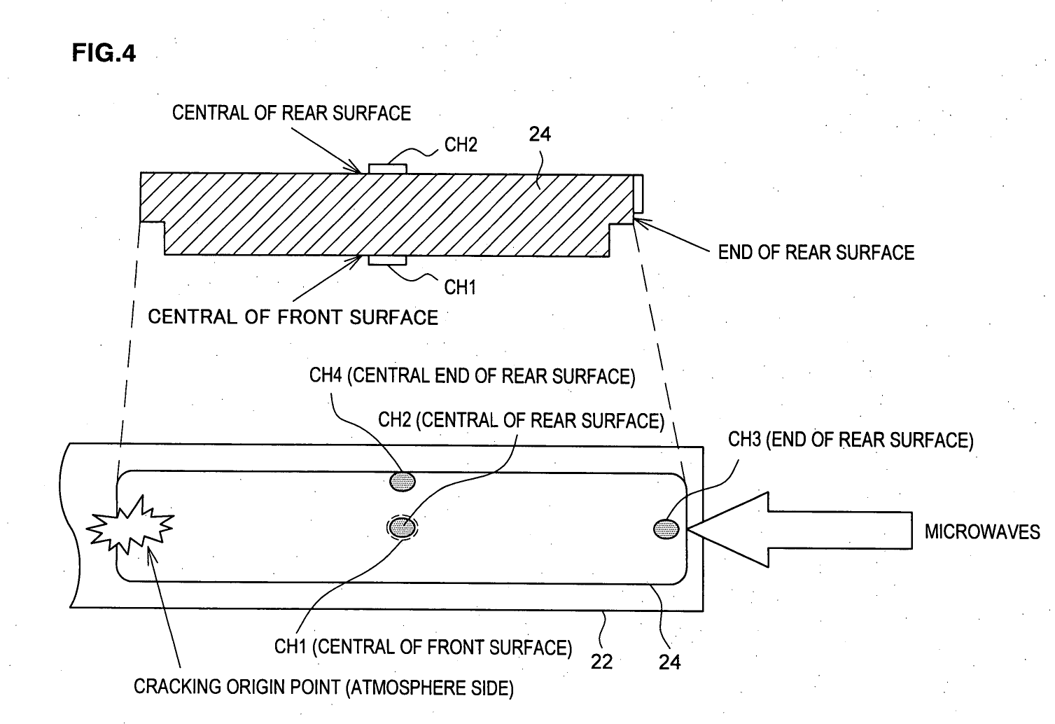

In order to investigate how cracking of the dielectric members 24 described above actually occurs, the inventor et al. conducted the following heat tests by using a burner. In the explanation, the lower surface of the dielectric member 24 is referred to as the front surface of the dielectric member 24, the upper surface of the dielectric member 24 is referred to as the rear surface of the dielectric member 24 and the end of the dielectric member 24 on the microwave entry side is referred to as the end of the rear surface of the dielectric member. The inventor et al. first installed a temperature sensor CH1 at the central of the front surface of the dielectric member 24, a temperature sensor CH2 at the central of the rear surface of the dielectric member 24, a temperature sensor CH3 at the end of the rear surface of the dielectric member 24 and a temperature sensor CH4 as an end at the central end of the rear surface of the dielectric member 24, as shown in FIG. 4. The distance between the temperature sensor CH2 and the temperature sensor CH4 was set to 38 mm.

The inventor et al. then monitored the temperatures detected with the temperature sensors CH2 and CH4 while heating the area around the central of the front surface of the dielectric member 24 with a burner. The dielectric member 24 became cracked when the difference between the detected temperatures reached approximately 50°. These results led to the conclusion that cracking occurs at the dielectric member 24 when a temperature difference of approximately 50° manifests inside the dielectric member 24.

In reality, the temperature of the dielectric member 24 sometimes rises to a level equal to or higher than 100° C. during plasma processing and the likelihood of the dielectric member 24 becoming cracked increases when a given internal temperature difference manifests in the dielectric member 24 of which the overall temperature is relatively high rather than when the same extent of internal temperature difference manifests in the dielectric member 24 of which the overall temperature is relatively low. Accordingly, the inventor et al. concluded that cracking conditions under which the dielectric member 24 becomes cracked are that there is a temperature difference equal to or greater than a predetermined temperature value manifesting within the dielectric member 24, that the predetermined temperature value is dependent on the temperature held in the overall dielectric member 24 (e.g., the average temperature at the dielectric member 24) and that the temperature difference equal to or greater than the predetermined temperature value decreases as the temperature of the overall dielectric member 24 becomes higher.

(Liquid Cooling Mechanism)

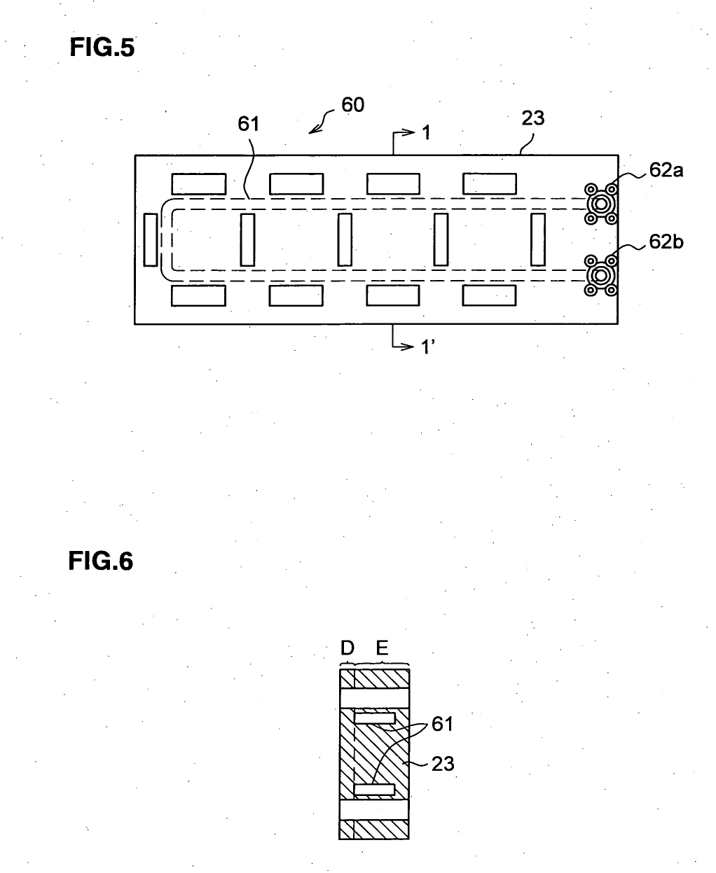

Based upon these findings, the inventor et al. conceived the structure that includes a first cooling unit 60 disposed in each slot antenna 23 so as to cool the dielectric member 24 with a liquid, as shown in FIG. 5. More specifically, the first cooling unit 60 is constituted with a flow passage 61, pipes connected via flanges 62a and 62b and a first cooling device (neither shown). As shown in FIG. 6 presenting a sectional view taken along 1-1′ in FIG. 5, the flow passage 61 is formed as an embedded passage within the slot antenna 23, by brazing a metal plate D with a thickness of 1 cm and a metal plate E with a thickness of 4 cm having an indented portion (groove portion) with a depth 3 cm formed therein to each other.

The first cooling device controls the coolant (e.g., Galden™ fluorine-based inert chemical solution) circulated through the flow passage 61 via the pipes. The first cooling unit 60 adopting such a structure liquid-cools the dielectric member 24 with the coolant. In addition, since the slot antenna 23 is constituted of a conductive material such as metal, as explained earlier, the heat at the dielectric member 24 can be released via the thermally conductive slot antenna 23 as the liquid coolant is circulated through the flow passage 61. As a result, the dielectric member 24 is effectively cooled (liquid-cooled).

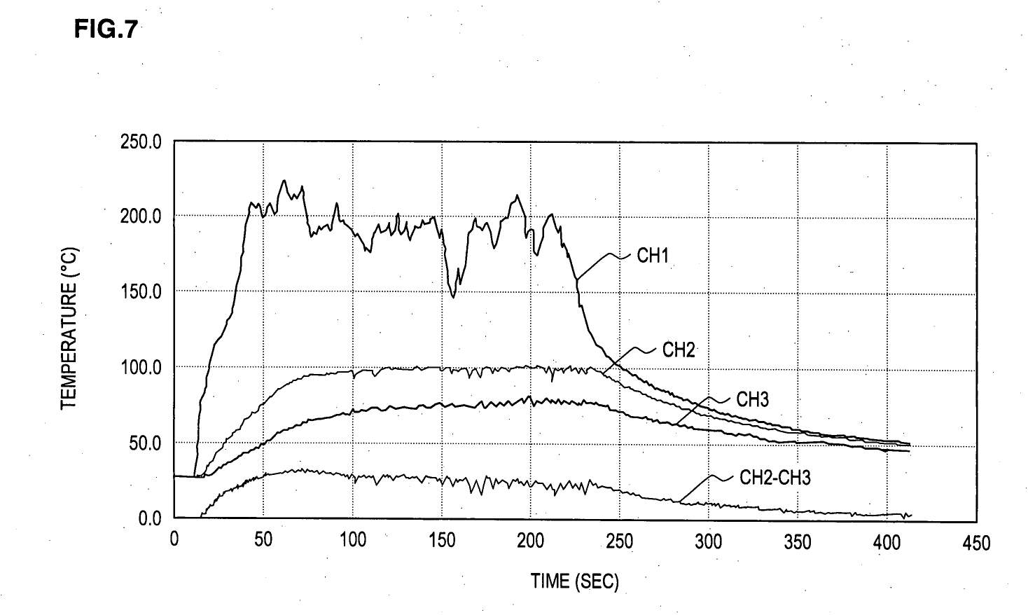

FIG. 7 presents test results obtained by overheating the central of the front surface of the dielectric member 24 with the burner while cooling the dielectric member 24 with the cooling mechanism (the first cooling unit 60) described above. The results indicate that the temperature difference (CH2−CH3) observed at the rear of the dielectric member 24 was 30° C. at the most. As explained earlier, the dielectric member 24 became cracked as the temperature difference at the dielectric member 24 heated with the burner increased to approximately 50° C. Based upon these observations, it was confirmed that by cooling the dielectric member 24 with the cooling mechanism (the first cooling unit 60) during the plasma processing, thermal damage to the dielectric member 24 during the plasma processing can be prevented.

(Air Cooling Mechanism)

In addition, the inventor et al. conceived a design that includes a second cooling unit 80 disposed at each waveguide 22 for purposes of cooling the dielectric member 24, as shown in FIG. 8. The second cooling unit 80 includes a gas intake port 81 formed in the area of the waveguide 22 connected to the microwave generator 33 and gas outlet ports 82 through 84 formed at the portion of the waveguide 22 inside the lid unit 20. Fine holes are formed in a mesh at the gas intake port 81 and the gas outlet ports 82 through 84. These each diameter of fine holes is a smaller than the wavelength λ (λ=122 mm) of the microwaves in free space. Thus, it is ensured that the microwaves propagated through the waveguide 22 are not leaked to the outside through these holes.

Through the gas intake port 81, a gas such as air is taken in. The air thus taken in flows through the waveguide 22 and is discharged through the gas outlet ports 82 through 84. The second cooling unit 80 creates a flow of a gas such as air inside the waveguide 22 and thus air-cools the dielectric member 24 disposed under the waveguide 22.

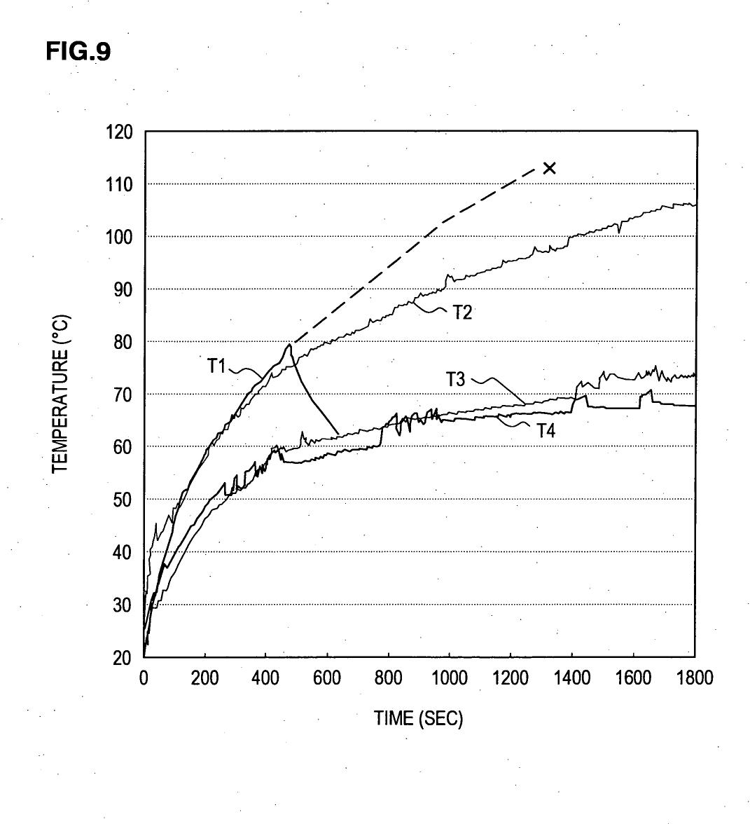

FIG. 9 presents test results obtained by the inventor et al. by cooling the dielectric member 24 with two cooling mechanisms (the first cooling unit 60 and the second cooling unit 80) during plasma processing. T1 through T4 each indicate a temperature detected at the temperature sensor CH2 (mounted at the central of the rear surface of the dielectric member 24) during the plasma processing. More specifically, T1 indicates the temperature detected without cooling the dielectric member 24 at all, T2 indicates the temperature measured by cooling (air-cooling) the dielectric member with the second cooling unit 80, T3 indicates the temperature measured by cooling (liquid cooling) the dielectric member with the first cooling unit 60 and T4 indicates the temperature measured by cooling the dielectric member with both the first cooling unit 60 and the second cooling unit 80.

The results indicate that the dielectric member 24 was cooled to a much greater extent by liquid-cooling the dielectric member 24 (T3) rather than by air-cooling the dielectric member 24 (T2). In addition, while the cooling effect on the dielectric member 24 is somewhat improved by both liquid-cooling and air-cooling the dielectric member 24 (T4) over the effect achieved by simply liquid-cooling the dielectric member 24 (T3), the extent of the improvement was not as significant as the difference in the cooling effect achieved by liquid-cooling the dielectric member rather than by air-cooling the dielectric member 24.

These findings led the inventor et al. to the conclusion that the dielectric member 24 can be cooled to great effect by liquid-cooling it with the first cooling unit 60. This conclusion was substantiated when the dielectric member 24 was liquid cooled by using the first cooling unit 60 without becoming cracked while plasma processing was executed with high-powered microwaves over an extended length of time, e.g., one hour or longer. In addition, the likelihood of cracking at the dielectric member 24 was further reduced by liquid-cooling the dielectric member 24 with the first cooling unit 60 and also air-cooling the dielectric member 24 with the second cooling unit 80 during plasma processing.

As described above, by adopting the embodiment in which the dielectric member 24 is liquid cooled via the first cooling unit 60, the risk of cracking occurring at the dielectric member 24 during plasma processing can be greatly reduced. In addition, the risk of cracking at the dielectric member 24 during the plasma processing can be further reduced by air cooling the dielectric member with the second cooling unit 80 while it is liquid cooled by the first cooling unit 60.

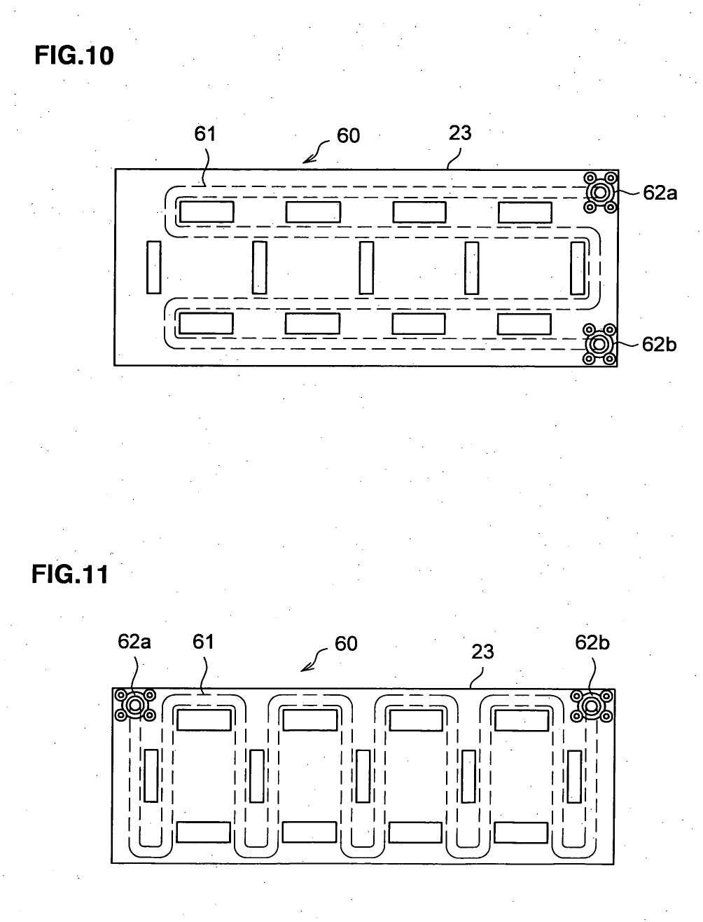

It is to be noted that the flow passage 61 constituting the first cooling unit 60 in the embodiment is formed in a U-shape at the slot antenna 23. However, the flow passage 61 at the first cooling unit 60 may assume a shape other than this, as long as a sufficiently large surface area is assured for the flow passage 61 so as to cool the dielectric member 24 effectively. For instance, the flow passage 61 may be formed at the slot antenna 24 in a W shape, as shown in FIG. 10, or the passage formed in the slot antenna 23 may assume a zigzag shape so as to form a plurality of W's side-by-side, as shown in FIG. 11.

Plasma is generated with the highest level of intensity under the slots (in particular, under the central slots). For this reason, the temperature of the dielectric member rises to an especially high level around the slots due to the plasma heat generated in the intense plasma. It is thus particularly desirable to form the flow passage 61 in a zigzag shape, as shown in FIG. 10 and FIG. 11 so as to increase the surface area of the flow passage 61 around the slots (especially near the central slots). As the liquid coolant flows through the flow passage near the slots, the temperature of the dielectric member around the slots can be lowered to great effect. Since this disallows any significant increase in the difference between the temperature at the dielectric member 24 specifically near the slots and the temperature at the other area of the dielectric member, thermal expansion of the dielectric member most likely to manifest near the slots can be prevented effectively. As a result, it is further ensured that the dielectric member does not crack during the process.

As explained above, the plasma processing apparatus according to one embodiment of the present invention includes a waveguide unit configured to propagate microwaves, a dielectric member configured to transmit the microwaves propagated via the waveguide unit, a first cooling unit configured to cool the dielectric member by using a liquid coolant, and a processing chamber configured to execute plasma processing on a substrate by raising a processing gas raised to plasma with the microwaves transmitted through the dielectric member.

When high-power microwaves are radiated in a plasma processing apparatus over an extended period of time, a dielectric member disposed at a position near the area where intense plasma is generated becomes rapidly heated to a very high temperature. The dielectric member becomes hot throughout its entirety, and its temperature at certain locations becomes particularly high. As a result, a significant difference in the temperature will occur within the dielectric member, leading to a manifestation of thermal stress, and the dielectric member may become cracked due to the thermal stress.

However, according to one embodiment of the present invention, the liquid coolant cools the dielectric member during the process. Thus, the temperature of the dielectric member is kept at a low level and the dielectric member does not thermally expand during the process. This means that significant thermal stress does not occur at the dielectric member and that the dielectric member does not crack during the process.

The plasma processing apparatus may further include a second cooling unit that cools the dielectric member with a gas coolant.

In such a plasma processing apparatus, the dielectric member is cooled both with the liquid coolant and with the gas coolant. Since this further reduces the thermal stress occurring at the dielectric member, the risk of the dielectric member becoming cracked during the process is further reduced.

The waveguide unit may include a waveguide through which the microwaves generated at a microwave generator are propagated and a slot antenna which directs the microwaves, having been propagated through the waveguide, to the dielectric member through a slot. In conjunction with such a waveguide unit, the first cooling unit may be achieved by forming a flow passage at the slot antenna and supplying a liquid to be used to cool the dielectric member through the flow passage.

In the structure, the dielectric member is directly cooled with the liquid flowing through the flow passage formed at the slot antenna. The slot antenna is normally disposed at a position between the waveguide and the dielectric member and in close contact with the dielectric member. The slot antenna, constituted of a metal such as aluminum, has good thermal conductivity. According to one embodiment of the present invention, a flow passage is formed at the slot antenna achieving good thermal conductivity and disposed in close contact with the dielectric member and a liquid is made to flow through the flow passage so as to cool the dielectric member effectively.

The second cooling unit may be achieved by forming a gas intake port and a gas outlet port at the waveguide, drawing the gas into the waveguide through the gas intake port and letting the gas out of the waveguide through the gas outlet port, thereby allowing the gas to flow through the waveguide.

In this case, as the gas flows from the gas intake port toward the gas outlet port at the waveguide, the dialectic member is indirectly cooled. The waveguide used to propagate the microwaves to the dialectic member via the slot, is disposed near the dielectric member. Thus, by cooling the waveguide, the dielectric member, too, is indirectly cooled.

A slot antenna may includes a slot through which microwaves are propagated toward a dielectric member and a flow passage through which a liquid coolant to be used to cool the dielectric member flows.

The flow passage formed at the slot antenna may be located near the slot.

Under normal circumstances, the slot opening at the slot antenna will be formed at a position at which the electromagnetic intensity of the microwaves propagated in the processing chamber is likely to at its highest. This means that plasma is generated with the highest intensity under the slot. As a result, the dielectric member present under the slot becomes rapidly heated to a very high temperature, resulting in a significant difference in the temperature between the portion of the dielectric member under the slot and the other areas of the dielectric member.

However, one embodiment of the present invention includes a flow passage formed near the slot so that the portion of the dielectric member near the slot is cooled particularly effectively by circulating a liquid through the flow passage. Thus, while the entire dielectric member is cooled, the portion of the dielectric member located under the slot, where the temperature rises to a high level, can be targeted for extra cooling. Consequently, the thermal stress in the dielectric member can be effectively lowered. This, in turn, prevents cracking of the dielectric member during the process.

A plasma processing method includes a step for propagating microwaves through a waveguide unit, a step for allowing the microwaves having been propagated via the waveguide unit to be transmitted through a dielectric member while supplying a liquid coolant through a flow passage formed at a slot antenna so as to cool the dielectric member, and a step for executing plasma processing on a substrate inside a processing chamber by raising a processing gas to plasma with the microwaves having been transmitted through the dielectric member.

In this method, the microwaves having been propagated via the waveguide unit are transmitted through the dielectric member while the dielectric member is cooled with the liquid coolant flowing through the flow passage at the slot antenna. As a result, the temperature of the dielectric member is kept to a low-level during the process. Since the thermal stress occurring at the dielectric member is reduced, cracking of the dielectric member during the process is prevented by adopting the method.

As explained above, a plasma processing apparatus, a slot antenna and a plasma processing method to be adopted to cool the dielectric member with a liquid coolant is provided.

While the invention has been particularly shown and described with respect to an embodiments thereof by referring to the attached drawings, the present invention is not limited to these examples and it will be understood by those skilled in the art that various changes in form and detail may be made therein without departing from the spirit, scope and teaching of the invention.

For instance, the dielectric member 24 is cooled (liquid cooled) by the first cooling unit 60 and is also cooled (air cooled) by the second cooling unit 80 in the embodiment. However, the present invention is not limited to this example and the dielectric member 24 may instead be cooled only by the first cooling unit 60, or by the second cooling unit 80 alone.

In addition, the flow passage 61 at the slot antenna 23 may be formed so as to contact the dielectric member 24, instead of by embedding the passage in the slot antenna 23.

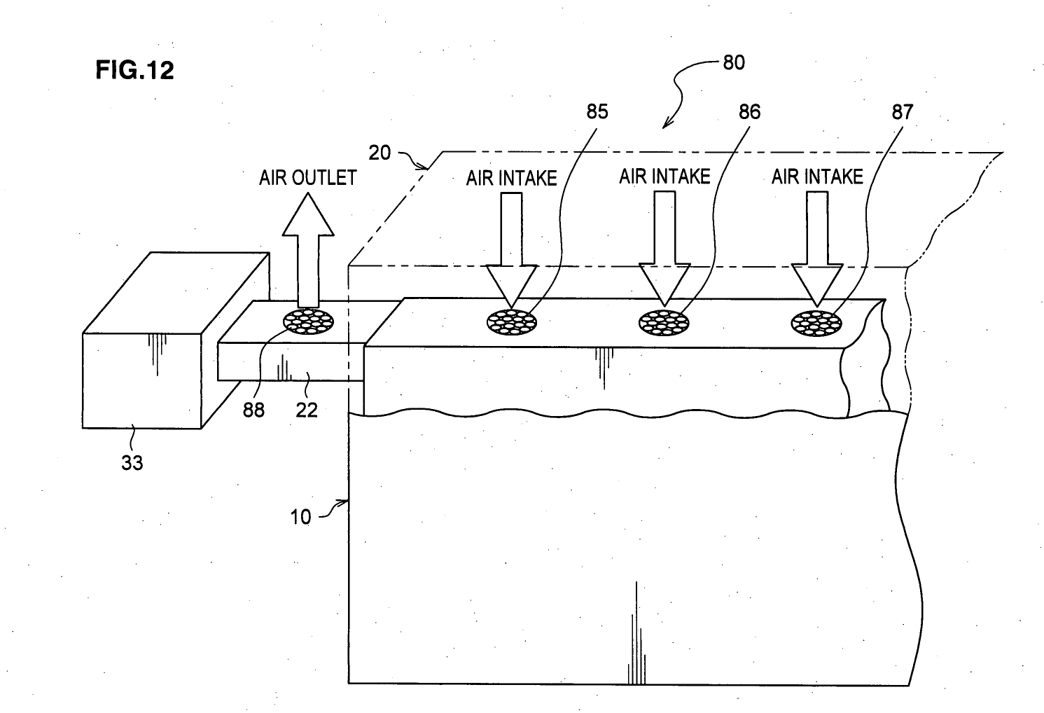

In the embodiment, the gas is taken in through the gas intake port 81 and is then discharged through the gas outlet ports 82 through 84 in the second cooling unit 80. However, the second cooling unit 80 according to the present invention is not limited to this example and instead, the second cooling unit 20 may adopt a structure shown in FIG. 12 that includes gas intake ports 85 through 87 formed over the area of the waveguide 22 located inside the lid unit 20 and a gas outlet port 88 disposed at the portion of the waveguide 22 where the waveguide is connected to the microwave generator 33, so as to take in the gas through the gas intake ports 85 through 87 and discharge the gas through the gas outlet port 88.

The present invention may be adopted in a plasma processing apparatus, a slot antenna and a plasma processing method, to cool a dielectric member with a liquid coolant.

What is claimed is;

1. A plasma processing apparatus for executing plasma processing on a substrate by using the plasma comprising:
a waveguide unit configured to propagate microwaves;
a dielectric member configured to transmit the microwaves propagated via the waveguide unit;
a first cooling unit configured to cool the dielectric member by using a liquid coolant; and
a processing chamber configured to execute plasma processing on a substrate by raising a processing gas raised to plasma with the microwaves transmitted through the dielectric member.

2. The plasma processing apparatus according to claim 1, further comprising:
a second cooling unit configured to cool the dielectric member by using a gas coolant.

3. The plasma processing apparatus according to claim 1, wherein:
the waveguide unit includes;
a waveguide configured to propagate the microwaves generated at a microwave generator; and
a slot antenna configured to transmit the microwaves propagated via the waveguide to the dielectric member through a slot, wherein:
the first cooling unit disposes a flow passage near the slot antenna and supplies the liquid coolant through the flow passage to cool the dielectric member.

4. The plasma processing apparatus according to claim 3, wherein:
the second cooling unit disposes a gas intake port and a gas outlet port at the waveguide, draws the gas into the waveguide through the intake port and lets the gas out of the waveguide through the gas outlet port so as to flow the gas in the waveguide.

5. A slot antenna comprising:
a slot configured to transmit microwaves toward a dielectric member; and
a flow passage configured to flow a liquid coolant to cool the dielectric member.

6. The slot antenna according to claim 5, wherein:
the flow passage is formed at the slot antenna is located near the slot.

7. A plasma processing method comprising:
a step for propagating microwaves through a waveguide unit;
a step for transmitting the microwaves through a dielectric member via the waveguide unit while supplying a liquid coolant through a flow passage formed at a slot antenna so as to cool the dielectric member; and
a step for executing plasma processing on a substrate in a processing chamber by raising a processing gas to plasma with the microwaves transmitted through the dielectric member.
